(19) United States
(12) Patent Application Publication
(10) Pub. No.: US 2010/0193805 A1
(43) Pub. Date: Aug. 5, 2010

(54) SEMICONDUCTOR LIGHT-EMITTING DEVICE

(75) Inventors: Naoki JOGAN, Tokyo (JP); Yuji Masui, Tokyo (JP); Rintaro Koda, Tokyo (JP); Takahiro Arakida, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sony Corporation, Tokyo (JP)

(21) Appl. No.: 12/648,706

(22) Filed: Dec. 29, 2009

(30) Foreign Application Priority Data
Feb. 2, 2009 (JP) 2009-021941

(51) Int. Cl. H01L 33/00; H01L 31/02

(52) U.S. Cl. 257/84; 257/E33.077

(57) ABSTRACT

A semiconductor light-emitting device includes a semiconductor light-emitting element including a first multilayer reflector, an active layer having a light-emitting region, and a second multilayer reflector in the stated order; a semiconductor light-detecting element disposed opposite the first multilayer reflector in relation to the semiconductor light-emitting element and including a light-absorbing layer configured to absorb light emitted from the light-emitting region; and an insulating oxidized layer disposed between the semiconductor light-emitting element and the semiconductor light-detecting element.

### BACKGROUND OF THE INVENTION

1. Field of the Invention

The present invention relates to semiconductor light-emitting devices including semiconductor light-emitting elements and semiconductor light-detecting elements, and particularly to a semiconductor light-emitting device suitable for applications where a semiconductor light-emitting element and a semiconductor light-detecting element are independently driven.

2. Description of the Related Art

A semiconductor light-emitting device used in the related art for applications such as optical fibers and optical disks has a light-detecting mechanism for detecting light emitted from a semiconductor light-emitting element built into the light-emitting device to keep the optical output level thereof constant. The light-detecting mechanism includes, for example, a reflector configured to split off a portion of the emitted light and a semiconductor light-detecting element configured to detect the split light. This mechanism, however, has a problem in that the number of components is increased and that the reflector and the semiconductor light-detecting element are to be accurately positioned relative to the semiconductor light-emitting element. One possible solution to that problem is to integrally form the semiconductor light-emitting element and the semiconductor light-detecting element.

However, if the two elements are integrally formed, the semiconductor light-detecting element can detect not only stimulated emission light, which is to be detected, but also spontaneous emission light. In this case, the optical output level of the semiconductor light-emitting element measured on the basis of the light detected by the semiconductor light-detecting element would contain the error corresponding to the spontaneous emission light. Thus, this method is unsuitable for applications where the optical output level is to be accurately controlled.

Japanese Unexamined Patent Application Publication No. 2007-150193 proposes a method of providing a metal layer having an opening between the semiconductor light-emitting element and the semiconductor light-detecting element. According to this method, the metal layer allows the light to be monitored, namely, stimulated emission light, to enter the semiconductor light-detecting element through the opening while reflecting the light not to be monitored, namely, spontaneous emission light, thus reducing the proportion of spontaneous emission light incident on the semiconductor light-detecting element.

### SUMMARY OF THE INVENTION

For the above integral semiconductor light-emitting device, the semiconductor light-emitting element and the semiconductor light-detecting element are independently driven for some applications or purposes. For example, the semiconductor light-emitting element and the semiconductor light-detecting element are often differentially driven to reduce the effect of external noise. To independently drive the semiconductor light-emitting element and the semiconductor light-detecting element, it is desirable to electrically insulate the two elements from each other.

Accordingly, for example, an undoped semiconductor layer may be provided between the semiconductor light-emitting element and the semiconductor light-detecting element. The undoped semiconductor layer, however, has insufficient insulation and therefore results in a high parasitic capacitance between the semiconductor light-emitting element and the semiconductor light-detecting element. This poses a problem in that an electrical crosstalk occurs when the semiconductor light-emitting element and the semiconductor light-detecting element are independently driven, thus decreasing optical detection accuracy.

Accordingly, it is desirable to provide a semiconductor light-emitting device in which no electrical crosstalk occurs between a semiconductor light-emitting element and a semiconductor light-detecting element.

A semiconductor light-emitting device according to an embodiment of the present invention includes a semiconductor light-emitting element including a first multilayer reflector, an active layer having a light-emitting region, and a second multilayer reflector in the stated order; a semiconductor light-detecting element disposed opposite the first multilayer reflector in relation to the semiconductor light-emitting element and including a light-absorbing layer configured to absorb light emitted from the light-emitting region; and an insulating oxidized layer disposed between the semiconductor light-emitting element and the semiconductor light-detecting element.

In the above semiconductor light-emitting device, the insulating oxidized layer is inserted between the semiconductor light-emitting element and the semiconductor light-detecting element. Unlike an undoped semiconductor layer, for example, the insulating oxidized layer is highly insulating, so that the parasitic capacitance that can occur between the semiconductor light-emitting element and the semiconductor light-detecting element is extremely low.

In the above semiconductor light-emitting device, because the insulating oxidized layer is inserted between the semiconductor light-emitting element and the semiconductor light-detecting element, the parasitic capacitance that can occur between the semiconductor light-emitting element and the semiconductor light-detecting element can be significantly reduced. This prevents an electrical crosstalk between the semiconductor light-emitting element and the semiconductor light-detecting element.

### BRIEF DESCRIPTION OF THE DRAWINGS

FIG. 1 is a sectional view of a semiconductor laser according to an embodiment of the present invention;

FIG. 2 is a sectional view illustrating a step of a process of producing the semiconductor laser in FIG. 1;

FIG. 3A is a sectional view illustrating a step following the step in FIG. 2;

FIG. 3B is a sectional view illustrating a step following the step in FIG. 3A;

FIG. 4 is a sectional view illustrating a step following the step in FIG. 3B;

FIG. 5 is a sectional view illustrating a step following the step in FIG. 4;

FIG. 6 is a sectional view of a variation of the semiconductor laser in FIG. 1;

FIG. 7 is a sectional view of another variation of the semiconductor laser in FIG. 1;

FIG. 8 is a sectional view of an oxidized layer in FIG. 7; and

FIG. 9 is a sectional view of another variation of the semiconductor laser in FIG. 1.

### DESCRIPTION OF THE PREFERRED EMBODIMENTS

An embodiment of the present invention will now be described in detail with reference to the drawings. The description will be given in the following order:

1. Structure

2. Production method

3. Advantages

4. Variations

### Structure

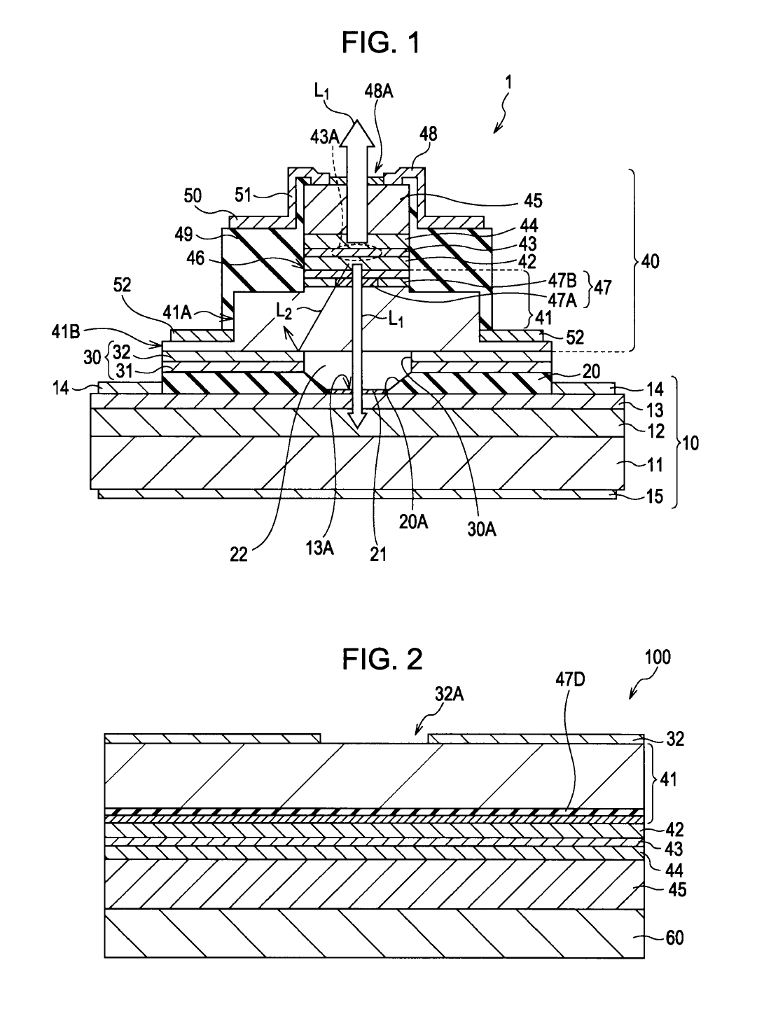

FIG. 1 shows an example of the sectional structure of a semiconductor laser 1 according to an embodiment of the present invention. The components of the semiconductor laser 1 are schematically illustrated in FIG. 1 and differ in size and shape from actual ones. This semiconductor laser 1 is formed by stacking an oxidized layer 20, a metal layer 30, and a semiconductor laser element 40 on a semiconductor light-detecting element 10 in the stated order. The semiconductor laser 1 corresponds to a specific example of a semiconductor light-emitting device, and the semiconductor laser element 40 corresponds to a specific example of a semiconductor light-emitting element.

The oxidized layer 20 is formed together with the semiconductor light-detecting element 10; therefore, they have no junction interface as formed, for example, after bonding. On the other hand, the semiconductor laser element 40 is bonded to the oxidized layer 20 with the metal layer 30 therebetween; therefore, they have a junction interface formed after the bonding. The semiconductor laser 1 integrally includes the semiconductor light-detecting element 10, the oxidized layer 20, the metal layer 30, and the semiconductor laser element 40. The semiconductor laser element 40 will be described first, and the other elements will be sequentially described thereafter.

### Semiconductor Laser Element 40

The semiconductor laser element 40 is a top-emitting laser formed by stacking, for example, a p-type distributed Bragg reflector (DBR) layer 41, a p-type cladding layer 42, an active layer 43, an n-type cladding layer 44, and an n-type DBR layer 45 on the metal layer 30 in the stated order. The top of the p-type DBR layer 41, the p-type cladding layer 42, the active layer 43, the n-type cladding layer 44, and the n-type DBR layer 45 constitute a columnar (cylindrical) mesa portion 46 having a diameter of, for example, about 30 μm. The middle portion of the p-type DBR layer 41 is formed so as to extend outward with respect to the mesa portion 46, and the outward-extending portion (middle portion 41A) serves as a base layer when an electrode pad 50, described later, is formed. The bottom portion of the p-type DBR layer 41 is formed so as to extend outward with respect to the middle portion of the p-type DBR layer 41, and the outward-extending portion (bottom portion 41B) serves as a base layer when a lower electrode 52, described later, is formed. The p-type DBR layer 41 corresponds to a first multilayer reflector, and the n-type DBR layer 45 corresponds to a second multilayer reflector.

The p-type DBR layer 41 is formed by alternately stacking low-refractive-index layers (not shown) and high-refractive-index layers (not shown). The low-refractive-index layers are formed of, for example, p-type Alₓ₁Ga₁₋ₓ₁As films (where 0<x1<1) having a thickness of λ₀/4n₁ (where λ₀ is the oscillation wavelength and n₁ is the refractive index). The high-refractive-index layers are formed of, for example, p-type Alₓ₂Ga₁₋ₓ₂As films (where 0<x2<x1) having a thickness of λ₀/4n₂ (where n₂ is the refractive index). Examples of the p-type impurity used include zinc (Zn), magnesium (Mg), and beryllium (Be).

The p-type cladding layer 42 is formed of, for example, p-type Alₓ₃Ga₁₋ₓ₃As (where 0<x3<1). The active layer 43 is formed of, for example, undoped Alₓ₄Ga₁₋ₓ₄As (where 0<x4<1). The active layer 43 has a light-emitting region 43A opposite a current-injecting region 47A, described later. The n-type cladding layer 44 is formed of, for example, n-type Alₓ₅Ga₁₋ₓ₅As (where 0≦x5<1). Examples of the n-type impurity used include silicon (Si) and selenium (Se).

The n-type DBR layer 45 is formed by alternately stacking low-refractive-index layers (not shown) and high-refractive-index layers (not shown). The low-refractive-index layers are formed of, for example, n-type Alₓ₆Ga₁₋ₓ₆As (where 0<x6<1) having a thickness of λ₀/4n₃ (where n₃ is the refractive index). The high-refractive-index layers are formed of, for example, n-type Alₓ₇Ga₁₋ₓ₇As films (where 0<x7<x6) having a thickness of λ₀/4n₄ (where n₄ is the refractive index).

The semiconductor laser element 40 also includes a current-narrowing layer 47, for example, in the p-type DBR layer 41. The current-narrowing layer 47 is provided at the position corresponding to, for example, the low-refractive-index layer that is several layers apart from the active layer 43 side in the p-type DBR layer 41 instead of that low-refractive-index layer. The current-narrowing layer 47 has a current-narrowing region 47B in the peripheral region thereof, with the central region forming the current-injecting region 47A. The current-injecting region 47A is formed of, for example, n-type Alₓ₈Ga₁₋ₓ₈As (where 0<x8≦1). The current-narrowing region 47B contains, for example, aluminum oxide (Al₂O₃) and, as described later, is formed by oxidizing an unoxidized layer 47D containing a high concentration of aluminum from the side surface thereof. Thus, the current-narrowing layer 47 functions to narrow a current. The current-narrowing layer 47 may instead be formed, for example, inside the n-type DBR layer 45, between the p-type cladding layer 42 and the p-type DBR layer 41, or between the n-type cladding layer 44 and the n-type DBR layer 45.

An upper electrode 48 is formed on the top surface of the mesa portion 46. The upper electrode 48 has, for example, an annular shape with an opening (aperture 48A) defined in a region including the region opposite the current-injecting region 47A. The upper electrode 48 may have another shape that does not block the region opposite the current-injecting region 47A. An insulating layer 49 is formed on the top surface (around the aperture 48A) and side surface of the mesa portion 46 and in the periphery thereof. The electrode pad 50, to which a wire (not shown) is to be bonded, and a connection portion 51 are provided on the surface of the insulating layer 49. The electrode pad 50 is electrically connected to the upper electrode 48 via the connection portion 51. The portion of the insulating layer 49 under the electrode pad 50 is made thicker than the rest of the insulating layer 49 to reduce parasitic capacitance. The lower electrode 52 is formed on the top surface of the bottom portion 41B of the p-type DBR layer 41.

The insulating layer 49 is formed of an insulating material such as an oxide or a nitride. The upper electrode 48, the electrode pad 50, and the connection portion 51 are formed by, for example, stacking a gold-germanium (Au—Ge) alloy film, a nickel (Ni) film, and a gold (Au) film in the stated order and are electrically connected to the top of the mesa portion 46. The lower electrode 52 is formed by, for example, stacking a titanium (Ti) film, a platinum (Pt) film, and a gold (Au) film in the stated order and is electrically connected to the p-type DBR layer 41.

### Semiconductor Light-Detecting Element 10

Of the light emitted from the light-emitting region 43A of the semiconductor laser element 40, the semiconductor light-detecting element 10 detects a component incident on the semiconductor light-detecting element 10. The semiconductor light-detecting element 10 is formed by, for example, stacking a light-absorbing layer 12 and a p-type contact layer 13 on an n-type substrate 11 in the stated order. In addition, an upper electrode 14 is provided on the top surface of the p-type contact layer 13 in a region other than the region opposite the semiconductor laser element 40, and a lower electrode 15 is provided on the backside of the n-type substrate 11.

The n-type substrate 11 is formed of, for example, n-type GaAs. The light-absorbing layer 12 is formed of, for example, n-type Alₓ₉Ga₁₋ₓ₉As (where 0<x9≦1). The light-absorbing layer 12 absorbs a portion of the light emitted from the light-emitting region 43A and converts the absorbed light into an electrical signal. This electrical signal is input to an optical-output arithmetic circuit (not shown) connected to the upper electrode 14 and the lower electrode 15 as an optical-output monitoring signal used in the optical-output arithmetic circuit to measure the output level of laser light L₁ emitted from the aperture 48A. The p-type contact layer 13 is formed of, for example, p-type Alₓ₁₀Ga₁₋ₓ₁₀As (where 0≦x10≦1) and is electrically connected to the light-absorbing layer 12 and the upper electrode 14.

### Oxidized Layer 20

The oxidized layer 20 electrically insulates the semiconductor laser element 40 and the semiconductor light-detecting element 10 from each other. The oxidized layer 20 is an insulating oxidized layer containing, for example, aluminum oxide (Al₂O₃). The oxidized layer 20 is formed by, for example, oxidizing an unoxidized layer (AlAs layer) containing a high concentration of aluminum, as described later. The oxidized layer 20 is sufficiently thicker than the current-narrowing layer 47 and is, for example, about 1 μm thick. Because the oxidized layer 20 is a thick film, the parasitic capacitance that can occur between the semiconductor laser element 40 and the semiconductor light-detecting element 10 is extremely low. Because the oxidized layer 20 is a thick film, additionally, the light-emitting region 43A of the semiconductor laser element 40 and a light-receiving region 13A of the semiconductor light-detecting element 10 are separated by a large distance. The light-receiving region 13A refers to a region in contact with a low-refractive-index layer 21 on the top surface of the p-type contact layer 13.

The oxidized layer 20 has an opening 20A under the mesa portion 46. The bottom of the opening 20A (portion corresponding to the light-receiving region 13A) is formed in a region including the region opposite the light-emitting region 43A, for example, in the region opposite the aperture 48A. The opening 20A is a passage through which a portion of the light emitted from the light-emitting region 43A travels toward the semiconductor light-detecting element 10, and is formed, for example, in the region opposite the aperture 48A. The portion of the oxidized layer 20 other than the opening 20A functions as a reflective layer for reflecting spontaneous emission light contained in the light emitted from the light-emitting region 43A. The low-refractive-index layer 21 is provided in the opening 20A, specifically, on the portion of the p-type contact layer 13 exposed in the bottom of the opening 20A. A void 22 is present in the opening 20A.

The low-refractive-index layer 21 is formed of, for example, a low-refractive-index material. The term “low-refractive-index material” herein refers to, for example, a material whose refractive index is higher than 1 (air) and is lower than that of the p-type contact layer 13, for example, a transparent material such as SiN (refractive index=2.0). The low-refractive-index layer 21 preferably has an optical thickness of (2n−1)×λ₀/4 (where n is a positive number). In this case, of the light with the wavelength λ₀ incident from the light-emitting region 43A, light reflected at the interface between the low-refractive-index layer 21 and the p-type contact layer 13 is 180° out of phase with light reflected at the interface between the void 22 and the low-refractive-index layer 21. As a result, the reflectance at the low-refractive-index layer 21 becomes substantially zero. That is, in this case, the low-refractive-index layer 21 functions as a nonreflective layer.

### Metal Layer 30

The metal layer 30 is provided to bond the semiconductor laser element 40 to the oxidized layer 20 and also functions as the lower electrode of the semiconductor laser element 40. The metal layer 30 has a multilayer structure including a metal layer 31 and a metal layer 32 in order from the oxidized layer 20 side. The metal layer 31 is formed by, for example, stacking a titanium (Ti) film, a platinum (Pt) film, and a gold (Au) film in order from the oxidized layer 20 side and is electrically connected to the metal layer 32. The metal layer 32 is formed by, for example, stacking a titanium (Ti) film, a platinum (Pt) film, and a gold (Au) film in order from the p-type DBR layer 41 side and is electrically connected to the p-type DBR layer 41 and the metal layer 31.

The metal layer 30 (metal layers 31 and 32) has an opening 30A in a region including the region opposite the light-emitting region 43A. The opening 30A is a passage through which a portion of the light emitted from the light-emitting region 43A travels toward the semiconductor light-detecting element 10, and is formed, for example, in the region opposite the aperture 48A. Accordingly, the portion of the metal layer 30 other than the opening 30A functions as a reflective layer for reflecting spontaneous emission light contained in the light emitted from the light-emitting region 43A.

### Production Method

The semiconductor laser 1 according to this embodiment can be produced, for example, as follows. FIGS. 2 to 5 show a process of producing the semiconductor laser 1 in the order in which the process proceeds. FIGS. 2 to 5 show the sectional structures of the individual elements during the production process.

The individual semiconductor layers are formed by, for example, metal-organic chemical vapor deposition (MOCVD). The source materials used for the III-V compound semiconductors are, for example, trimethylaluminum (TMA), trimethylgallium (TMG), trimethylindium (TMIn), and arsine (AsH₃). The source material used for the donor impurity is, for example, H₂Se, and the source material used for the acceptor impurity is, for example, dimethylzinc (DMZ).

Specifically, first, the n-type DBR layer 45, the n-type cladding layer 44, the active layer 43, the p-type cladding layer 42, and the p-type DBR layer 41 are formed on a substrate 60 of, for example, n-type GaAs in the stated order (FIG. 2). In this step, the unoxidized layer 47D is formed, for example, as part of the p-type DBR layer 41. The unoxidized layer 47D is a layer that is to be oxidized in an oxidation step, described later, to form the current-narrowing layer 47 and that contains, for example, AlAs. The metal layer 32 is then formed on the p-type DBR layer 41 so as to have an opening 32A. Thus, a first substrate 100 is formed.

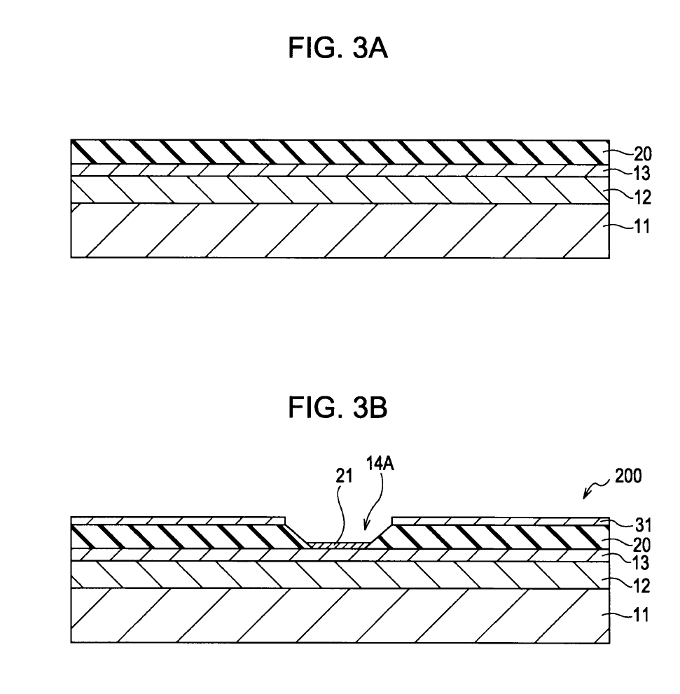

On the other hand, the light-absorbing layer 12, the p-type contact layer 13, and an unoxidized layer (not shown) are formed on the substrate 11 in the stated order. This unoxidized layer is a layer that is to be oxidized in a subsequent oxidation step to form the oxidized layer 20 and that contains, for example, AlAs. The unoxidized layer is sufficiently thicker than the unoxidized layer 47D and is, for example, about 1 μm thick. The unoxidized layer on the p-type contact layer 13 is then selectively oxidized by oxidation treatment at high temperature in a water vapor atmosphere. As a result, the entire unoxidized layer is oxidized to become insulating. Thus, the oxidized layer 20 is formed on the p-type contact layer 13 (FIG. 3A).

Next, an opening 14A is formed in part of the oxidized layer 20, and the low-refractive-index layer 21 is formed on the bottom of the opening 14A. The metal layer 31 is then formed on the top surface of the oxidized layer 20 so as to have an opening in the region opposite the opening 14A (FIG. 3B). Thus, a second substrate 200 is formed.

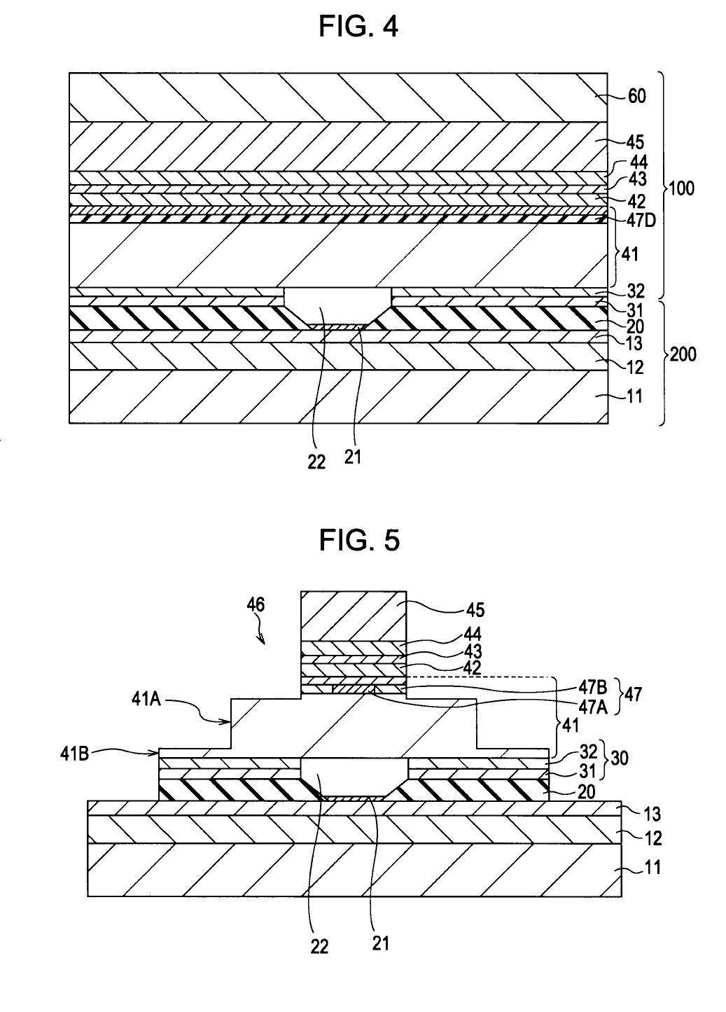

Next, the first substrate 100 is bonded to the metal layer 31 of the second substrate 200 with the metal layer 32 facing the metal layer 31 (FIG. 4). As a result, the metal layers 31 and 32 are bonded together, and the void 22 is formed between the low-refractive-index layer 21 and the p-type DBR layer 41.

Next, the substrate 60 is removed, and the n-type DBR layer 45, the n-type cladding layer 44, the active layer 43, the p-type cladding layer 42, the p-type DBR layer 41, and the unoxidized layer 47D are selectively removed. As a result, the mesa portion 46 is formed, and steps (middle portion 41A and bottom portion 41B) are formed on the p-type DBR layer 41 (FIG. 5).

Next, the unoxidized layer 47D is selectively oxidized from the side surface of the mesa portion 46 by oxidation treatment at high temperature in a water vapor atmosphere. As a result, the peripheral region of the unoxidized layer 47D becomes an insulating layer (aluminum oxide). Accordingly, the current-narrowing region 47B is formed in the peripheral region, with the central region serving as the current-injecting region 47A. Thus, the current-narrowing layer 47 is formed (FIG. 1).

Subsequently, the insulating layer 49, the upper electrodes 14 and 48, the electrode pad 50, the connection portion 51, and the lower electrodes 15 and 52 are formed (FIG. 1). Thus, the semiconductor laser 1 according to this embodiment is produced.

In the semiconductor laser 1 according to this embodiment, the semiconductor laser element 40 and the semiconductor light-detecting element 10 are independently driven. For example, a voltage is applied between the upper electrode 48 and the metal layer 30 in phase with each other so that the potential difference between the upper electrode 48 and the metal layer 30 remains constant. On the other hand, a voltage is applied between the upper electrode 14 and the lower electrode 15 in phase with each other and 180° out of phase with the voltage applied between the upper electrode 48 and the metal layer 30 so that the potential difference between the upper electrode 14 and the lower electrode 15 remains constant.

A current narrowed by the current-narrowing layer 47 is injected into the light-emitting region 43A, the gain region of the active layer 43, thus causing emission of light through recombination of electrons and holes. Although this light contains both stimulated emission light and spontaneous emission light, laser oscillation occurs at the wavelength λ₀ (for example, 850 nm) as stimulated emission is repeated inside the element 40. As a result, the light L₁ having the wavelength λ₀ is output from the aperture 48A to exit outside, and at the same time is slightly output from the p-type DBR layer 41 toward the semiconductor light-detecting element 10. A portion of the light passes through the void 22 and the low-refractive-index layer 21 to reach the light-absorbing layer 12 (FIG. 1).

The light incident on the light-absorbing layer 12 is absorbed by the light-absorbing layer 12 and is converted into an electrical signal (photocurrent) corresponding to the output level of the absorbed light. The electrical signal is output to an optical-output arithmetic circuit (not shown) via wires (not shown) electrically connected to the upper electrode 14 and the lower electrode 15 and is received by the optical-output arithmetic circuit as an optical-output monitoring signal. Thus, the output level of the light incident on the light-absorbing layer 12 is measured.

As described above, if noise enters the semiconductor laser element 40 or the semiconductor light-detecting element 10 when they are differentially driven, the noise can be cancelled. This allows the semiconductor laser element 40 to provide a stable optical output unaffected by noise and the semiconductor light-detecting element 10 to output an electrical signal unaffected by noise.

### ADVANTAGES

In this embodiment, the insulating oxidized layer 20 is inserted between the semiconductor laser element 40 and the semiconductor light-detecting element 10. Unlike an undoped semiconductor layer, for example, the insulating oxidized layer 20 is highly insulating, so that the parasitic capacitance that can occur between the semiconductor laser element 40 and the semiconductor light-detecting element 10 is extremely low. The insulating oxidized layer 20 can therefore prevent an electrical crosstalk when the semiconductor laser element 40 and the semiconductor light-detecting element 10 are independently driven. This allows stable driving of the semiconductor laser element 40 and improves the optical detection accuracy of the semiconductor light-detecting element 10. In addition, because an electrical crosstalk is prevented, the semiconductor laser element 40 and the semiconductor light-detecting element 10 can be independently driven at high speed and support, for example, differential driving for 10 Gbps optical communication.

In this embodiment, along with the oxidized layer 20, the metal layer 30 having the opening 30A is inserted between the semiconductor laser element 40 and the semiconductor light-detecting element 10. The metal layer 30 reflects most of spontaneous emission light L₂ contained in the light emitted from the light-emitting region 43A, and the oxidized layer 20, exposed in the opening 30A, slightly reflects the light L₂ as well. On the other hand, most of the stimulated emission light L₁ contained in the light emitted from the light-emitting region 43A passes through the opening 30A to reach the exposed portion 13A. Thus, the proportion of spontaneous emission light in the light incident in the light-receiving region 13A can be sufficiently reduced. As a result, the level of spontaneous emission light detected by the semiconductor light-detecting element 10 can be reduced to improve the optical detection accuracy.

In this embodiment, additionally, an insulating layer (oxidized layer 20) electrically insulating the semiconductor laser element 40 and the semiconductor light-detecting element 10 can be formed by oxidation treatment of, for example, an AlAs layer (unoxidized layer 20D). This facilitates the formation of an insulating layer, particularly, the formation of a thick insulating layer.

### VARIATIONS

While the present invention has been described above with reference to the embodiment, the present invention is not limited to the above embodiment, and various modifications are permitted.

For example, although the semiconductor materials used in the above embodiment are GaAs-based compound semiconductors, other material systems such as GaInP-based (red) materials and AlGaAs-based (infrared) materials can also be used.

Although the conductivity types of semiconductors are exemplified in the above embodiment, the conductivity types opposite to the exemplary conductivity types can also be used. For example, it is possible to replace “p-type” with “n-type” and to replace “n-type” with “p-type” in the above embodiment.

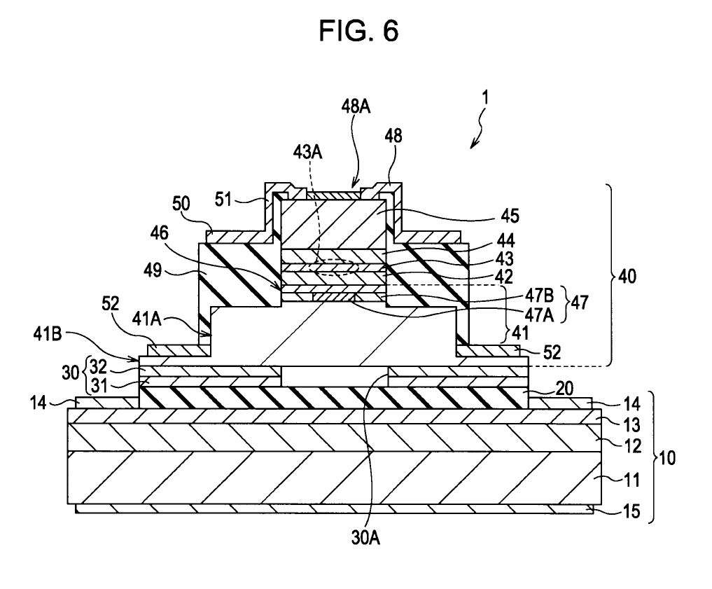

Although the oxidized layer 20 has the opening 20A in the above embodiment, the opening 20A can be omitted, for example, as shown in FIG. 6, if reflection at the oxidized layer 20 is negligible.

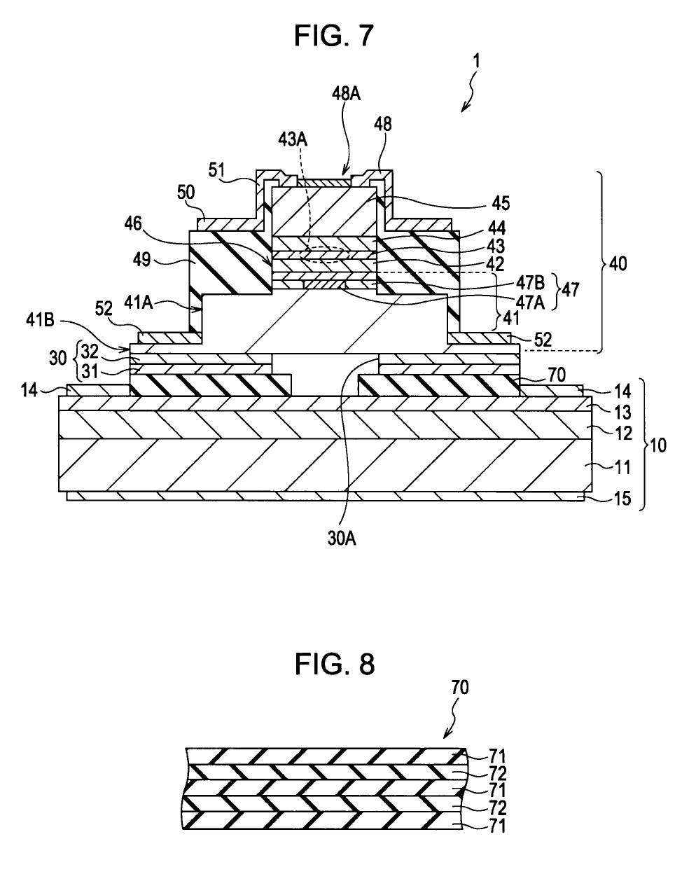

Although the oxidized layer 20 has a monolayer structure in the above embodiment, it may also have a multilayer structure. For example, as shown in FIG. 7, the oxidized layer 20 can be replaced with an oxidized layer 70 having a multilayer structure. For example, as shown in FIG. 8, the oxidized layer 70 is formed by alternately stacking first thin films 71 and second thin films 72. The bottommost first thin film 71 is in contact with the p-type contact layer 13, whereas the topmost first thin film 71 is in contact with the metal layer 31. The first thin films 71 contain a semiconductor material that is relatively difficult to oxidize (relative to the material of the second thin films 72 before oxidation). The first thin films 71 contain, for example, undoped GaAs. The second thin films 72 contain an oxide of a semiconductor material that is relatively easy to oxidize (relative to the first thin films 71). The second thin films 72 contain, for example, aluminum oxide (Al₂O₃) and are formed by, for example, oxidizing AlAs layers containing a high concentration of aluminum. Accordingly, both the first thin films 71 and the second thin films 72 are insulating, although the second thin films 72 are much more insulating than the first thin films 71.

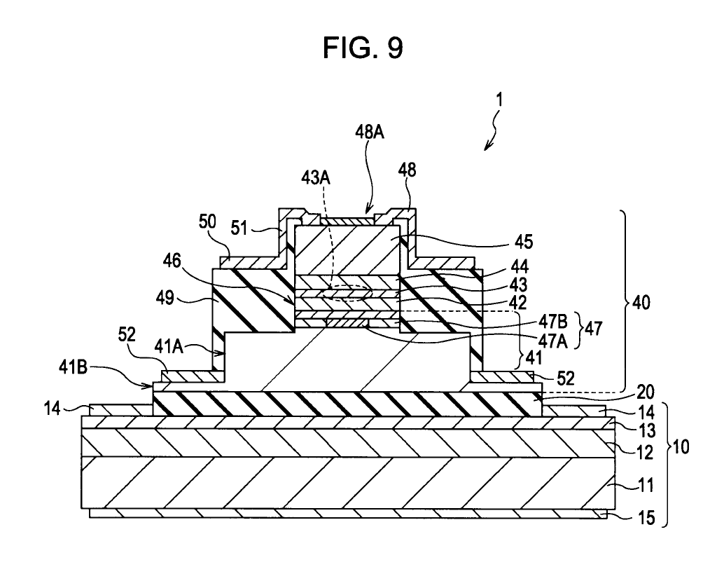

Although the semiconductor laser element 40 and the semiconductor light-detecting element 10 are bonded together with the metal layer 30 therebetween in the above embodiment, they may be integrally formed by another method. For example, the semiconductor laser element 40 may be formed in direct contact with the oxidized layer 20 with no component therebetween. For example, as shown in FIG. 9, the semiconductor laser element 40 may be formed on the p-type contact layer 13 of the semiconductor light-detecting element 10 with a flat oxidized layer 20 having no opening therebetween. However, it is difficult to form the semiconductor laser element 40 on the oxidized layer 20 by crystal growth after the formation of the oxidized layer 20. Therefore, the following technique may be employed.

Specifically, first, an unoxidized layer (not shown) is formed on the p-type contact layer 13 of the semiconductor light-detecting element 10. Next, the p-type DBR layer 41, the p-type cladding layer 42, the active layer 43, the n-type cladding layer 44, and the n-type DBR layer 45 are formed on the unoxidized layer in the stated order and are selectively removed to form the portions such as the mesa portion 46. The unoxidized layer 47D and the unoxidized layer on the p-type contact layer 13 are then selectively oxidized from the side surfaces thereof by oxidation treatment at high temperature in a water vapor atmosphere. The unoxidized layer 47D and the unoxidized layer on the p-type contact layer 13 may be oxidized either simultaneously or separately. As a result, the peripheral region of the unoxidized layer 47D becomes an insulating layer (aluminum oxide). Accordingly, the current-narrowing region 47B is formed in the peripheral region, with the central region serving as the current-injecting region 47A. Thus, the current-narrowing layer 47 is formed. On the other hand, the entire unoxidized layer 20D on the p-type contact layer 13 is oxidized to become insulating. Thus, the oxidized layer 20 is formed on the p-type contact layer 13.

The present application contains subject matter related to that disclosed in Japanese Priority Patent Application JP 2009-021941 filed in the Japan Patent Office on Feb. 2, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor light-emitting device comprising:
a semiconductor light-emitting element including a first multilayer reflector, an active layer having a light-emitting region, and a second multilayer reflector in the stated order;
a semiconductor light-detecting element disposed opposite the first multilayer reflector in relation to the semiconductor light-emitting element and including a light-absorbing layer configured to absorb light emitted from the light-emitting region; and
an insulating oxidized layer disposed between the semiconductor light-emitting element and the semiconductor light-detecting element.

2. The semiconductor light-emitting device according to claim 1, wherein
the semiconductor light-emitting element includes a current-narrowing layer configured to narrow a current injected into the semiconductor light-emitting element; and
the oxidized layer is thicker than the current-narrowing layer.

3. The semiconductor light-emitting device according to claim 1, wherein the oxidized layer is formed by alternately stacking first thin films containing a semiconductor material that is relatively difficult to oxidize and second thin films containing an oxide of a semiconductor material that is relatively easy to oxidize.

4. The semiconductor light-emitting device according to claim 1, wherein
the semiconductor light-emitting element includes an annular electrode disposed on the second multilayer reflector, the annular electrode having an aperture in a region including a region opposite the light-emitting region; and
the oxidized layer has an opening in a region opposite the aperture.

5. The semiconductor light-emitting device according to claim 1, further comprising a metal layer disposed between the semiconductor light-emitting element and the oxidized layer to bond the semiconductor light-emitting element and the oxidized layer.

6. The semiconductor light-emitting device according to claim 1, wherein the semiconductor light-emitting element is disposed in direct contact with the oxidized layer.
